(19) United States
(12) Patent Application Publication
(10) Pub. No.: US 2024/0290680 A1
(43) Pub. Date: Aug. 29, 2024

(54) LOW-PROFILE MEMORY APPARATUS COMPATIBLE WITH SYSTEM THERMAL SOLUTIONS AND METHOD FOR MAKING SAME

(71) Applicant: Intel Corporation, Santa Clara, CA (US)

(72) Inventors: Jiun Hann Sir, Gelugor (MY); Poh Boon Khoo, Bayan Lepas (MY)

(73) Assignee: Intel Corporation, Santa Clara, CA (US)

(21) Appl. No.: 18/115,711

(22) Filed: Feb. 28, 2023

(51) Int. Cl. H01L 23/367; H01L 21/48; H01L 23/373

(52) U.S. Cl. CPC H01L 23/367; H01L 21/4871; H01L 23/3736

(57) ABSTRACT

A low-profile memory apparatus that is compatible with system thermal solutions. The apparatus includes a substrate layer with an upper surface and a lower surface, a portion of the substrate layer having a first arrangement of conductive contacts located on the lower surface. A memory package is inverted and attached to the first arrangement of conductive contacts. A heat spreader component comprising a cavity is included. The memory package and the portion of the substrate layer having the first arrangement of conductive contacts located in the cavity. A second arrangement of conductive contacts is located on the lower surface of the substrate layer, external to the heat spreader component, to attach the apparatus to another substrate or printed circuit board in a multi-die assembly.

### BACKGROUND

Many multi-die package assemblies include components with different profiles, or “z-heights.” For example, a memory package component can have a larger z-height than the height of a central processing unit (CPU) or graphics processing unit (GPU) that the memory package component is paired with in the multi-die package. This difference in profile or z-height can cause system thermal management to become a complex technical problem to solve. Accordingly, continued improvements to system thermal solutions are desirable.

### BRIEF DESCRIPTION OF THE DRAWINGS

FIGS. 1A-1B are simplified cross-sectional views of a low-profile memory apparatus, in accordance with various embodiments disclosed herein.

FIG. 1C illustrates a low-profile memory apparatus assembled with a processor package on a motherboard, in accordance with various embodiments disclosed herein.

FIGS. 2A-2B illustrate that embodiments are compatible with a system thermal solution, in accordance with various embodiments disclosed herein.

FIG. 2C is a simplified three-dimensional view of a heat-spreader component for the low-profile memory apparatus, in accordance with various embodiments disclosed herein.

FIG. 2D is a top-down view of an exemplary mid-frame interposer that may be included in any of the embodiments disclosed herein.

FIGS. 3A-3C and FIG. 4 are simplified cross-sectional views showing additional embodiments of a low-profile memory apparatus, in accordance with various embodiments disclosed herein.

FIG. 5 illustrates example process steps for a method for manufacturing and implementing a low-profile memory apparatus, in accordance with various embodiments disclosed herein.

FIG. 6 is a top view of a wafer and dies that may be included in a microelectronic assembly, in accordance with any of the embodiments disclosed herein.

FIG. 7 is a simplified cross-sectional side view showing an implementation of an integrated circuit on a die that may be included in various embodiments, in accordance with any of the embodiments disclosed herein.

FIG. 8 is a cross-sectional side view of a microelectronic assembly that may include any of the embodiments disclosed herein.

FIG. 9 is a block diagram of an example electrical device that may include any of the embodiments disclosed herein.

### DETAILED DESCRIPTION

Combining components with different profiles, or “z-heights” into a multi-die package introduces technical challenges for system thermal management. In a non-limiting example, a delta height difference can occur when a memory package component has a larger z-height than the z-height of die that it is paired with (e.g., a central processing unit (CPU) die, or a graphics processing unit (GPU) die) in the multi-die package or assembly.

Some proposed solutions address the delta height difference by adding intermediate heat spreader component above components with a lower z-height to achieve a same profile or z-height across the multi-die assembly or package. In this approach, a planar system thermal management solution, such as a planar system heat spreader, may be implemented. However, a drawback of this approach is its overall higher profile, or higher z-height than is desirable. As products and devices evolve, lower-profile components are required.

Embodiments disclosed herein propose a technical solution to the above-described technical problems in the form of a low-profile memory apparatus that is compatible with system thermal solutions. The provided embodiments reduce system thermal challenges and associated cost. The provided embodiments enable thinner systems, devices, and products. These concepts are developed in more detail below.

Example embodiments are hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

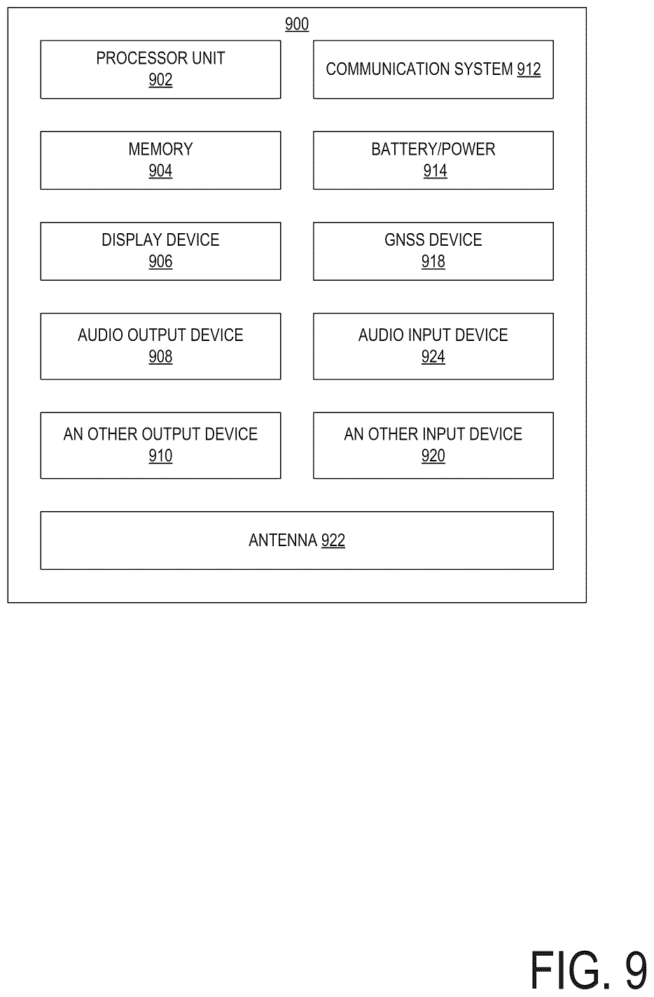

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (see, e.g., FIG. 9 discussion for processor unit 902 definition), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

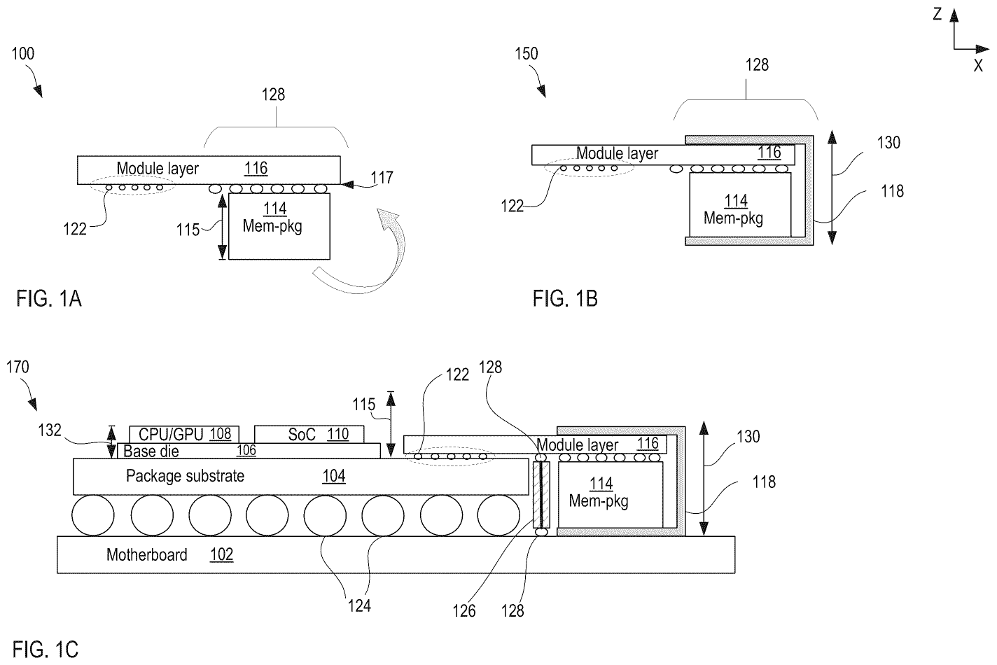

FIGS. 1A-1B are simplified cross-sectional views of a low-profile memory apparatus, in accordance with various embodiments disclosed herein. Embodiment 100 includes a memory package 114 component attached to a substrate layer that is referred to herein as a module layer 116 to distinguish it from other substrate layers.

As represented with the arrow in FIG. 1A, the memory package 114 component is “inverted,” “reversed,” or upside down, having its contacts on an upper surface. The module layer 116 is oriented to have a connectivity surface that is a lower surface 117. A portion of the module layer 116 (on the right in the figures) has a first arrangement 128 of conductive contacts on the lower surface 117. In various embodiments, the upper surface of the inverted memory package 114 component is attached to the lower surface 117 of the module layer 116 via solder bumps on the first arrangement 128, as illustrated.

In various embodiments, the module layer 116 further has a second arrangement 122 of conductive contacts on the lower surface, located away from the first portion, and used for connectivity between the low-profile memory apparatus (and, in particular, the memory package 114 component) and other components in a multi-die assembly, as described in more detail below. Accordingly, the first arrangement 128 and the second arrangement 122 may have different dimensions and different pitches from each other. Solder bumps are optionally indicated on a second arrangement 122 of conductive contacts in embodiment 100 and embodiment 150, however, solder bumps on the second arrangement 122 may be omitted from embodiment 100 and embodiment 150 yet implemented in the manufacture of embodiment 170.

In various embodiments, the memory package 114 component and the portion of the module layer 116 having the first arrangement 128 of conductive contacts may be partially enclosed by a means for spreading heat, such as a heat spreader component. Embodiment 150 illustrates a low-profile memory apparatus with a non-limiting example of a heat spreader component 118. The heat spreader component 118 is to dissipate heat during operation of the memory package 114 component.

In various embodiments, the heat spreader component 118 may be described as having a cavity, the cavity sized and shaped to partially enclose the memory package 114 component plus the portion of the module layer having first arrangement 128, as illustrated. Said differently, the memory package 114 component and portion of the module layer 116 that includes the first arrangement 128 are located in the cavity. Said another way, the heat spreader component 118 is located around the portion of the module layer 116 that includes the first arrangement 128 and around the memory package 114 component.

In two dimensions (FIG. 1B and FIG. 1C), “partially enclosing” may mean the heat spreader component 118 appears c shaped, extending over a portion of an upper surface of the module layer 116 (e.g., the portion of the module layer 116 having the first arrangement 128), along a side of the memory package 114 component, and below a portion of a lower surface of the memory package 114 component. In three-dimensions, “partially enclosing” may embody two substantially planar plates (e.g., a top plate and a bottom plate, the top plate and the bottom plate being substantially the same size and having an area that is substantially equal to an area of the upper and lower surface of the memory package 114 component), attached on one side to a wall having a “z-height” 130.

The heat spreader component 118 comprises a thermally conductive material. In various embodiments the heat spreader component 118 is metal. In some embodiments, the heat spreader component 118 comprises aluminum. In other embodiments, the heat spreader component 118 may comprise copper.

The second arrangement 122 is located away from, or external to, the means for thermal management or the heat spreader component 118. As mentioned, the module layer 116, via at least the second arrangement 122, can provide connectivity between the low-profile memory apparatus (and, in particular, the memory package 114 component) and other components in a multi-die assembly. In a non-limiting example, FIG. 1C illustrates the low-profile memory apparatus of embodiment 100 and embodiment 150 assembled with a processor package. As used herein, the processor package comprises a central processing unit (CPU) or graphics processing unit (GPU) die 108 and a system on chip (SoC) 110. In various embodiments, the CPU 108 die and SoC 110 die may operate at conventionally high speeds, wherein “high speed” means greater than 6 GHz. The processor package may further employ a base die 106 that functions as an interposer, providing routing and connections for the CPU 108 die and SoC 110 die, which are operably connected thereto, e.g., by a solder attach.

The CPU/GPU 108, SoC 110, and base die 106 may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. As may be appreciated, this arrangement of die is just one example embodiment, in other multi-die assemblies, there may be a different arrangement of die that serve various other functions.

The processor package (CPU 108, SoC 110, base die 106) may be attached to a package substrate 104. The package substrate 104 enables the components making up the processor package to communicate with other die in an assembly package, such as other die attached to the package substrate 104. In various embodiments, the package substrate 104 may comprise a printed circuit board, thin-film substrate, or another suitable substrate. In other embodiments, the package substrate 104 may further be attached (e.g., via solder bumps 124) to a motherboard 102 or printed circuit board (PCB).

A height 115 of the memory package 114 component is indicated. The z-height 130 of the low-profile memory apparatus represents a combined height of the heat spreader component 118, the memory package 114, the module layer 116, and associated means for attachment, such as solder bumps 128. While the drawings are not necessarily to scale, it is intentional that the height 115 of the memory package 114 is larger than a combined height 132 of the base die 106 plus the CPU 108, and/or the height 115 of the memory package 114 is larger than a combined height 132 of the base die 106 plus the SoC 110. As follows, viewing the figures, it is observable that placing the memory package 114 component on the package substrate 104 (i.e., on the surface that includes the processor package) would raise the z-height of the overall assembly. Accordingly, embodiments of the low-profile memory apparatus, such as embodiment 150, enable a lower z-height assembly.

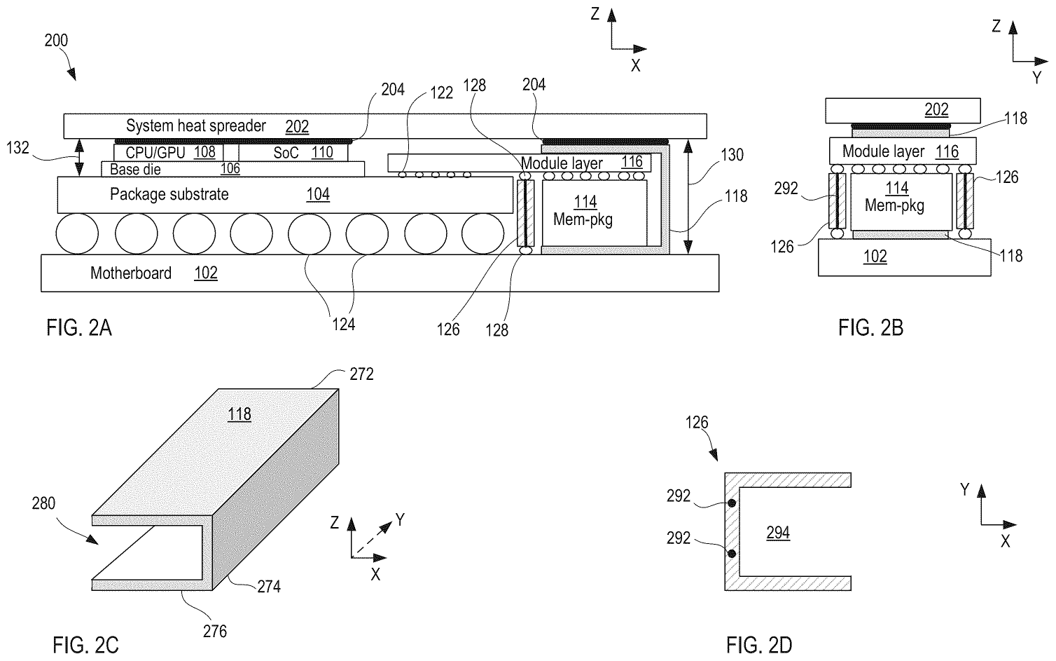

In various embodiments, an interposer 126 component may be employed. The interposer 126 may perform one or more functions, as described in connection with FIG. 2D, below. The interposer is shown attached with solder bumps 128.

FIGS. 2A and 2B provide a front and a side view of an example multi-die assembly 200 that implements the low-profile memory apparatus of FIG. 1A and/or FIG. 1B. The multi-die assembly 200 includes a processor package, as described in connection with FIG. 1C. In other embodiments, the multi-die assembly 200 may include additional IC die attached to the package substrate 104.

As shown in FIGS. 2A-2B, in various embodiments, a means for thermal management, or system thermal solution 202 may be implemented. The means for thermal management or system thermal solution 202 may include a system head spreader component, a vapor chamber, a heat pipe, a heat sink, or a liquid-cooled cold plate attached to the multi-die assembly 200. As part of a system thermal solution, a thermal conduction layer interface material (TIM) 204 may be located over the die and under the system thermal solution 202. The TIM 204 can be any suitable material, such as a silver particle-filled thermal compound, thermal grease, phase change materials, indium foils, or graphite sheets. The system thermal solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM 204 can be of substantially uniform thickness between the cooling component and the integrated circuit dies of varying thicknesses. Thermal management solutions can also include an integrated heat spreader. In other embodiments, the die in the multi-die assembly 200 can be overmolded with an encapsulant. The encapsulant can comprise a molding compound, dielectric materials, metal, ceramic, plastic, or a combination thereof.

As mentioned above, and illustrated in FIG. 2C, the heat spreader 118 component may be characterized by a top 272 plate, a bottom 276 plate and an edge wall 274 of z-height 130. The heat spreader 118 component is substantially rectangular, or c shaped, having a cavity 280 that fits around a memory package 114 plus a portion of the module layer 116, as illustrated. Note that the top plate and bottom plate are substantially the same size. Note also that the module layer 116 extends out from the cavity 280, such that the area that includes solder bumps 122 is not inside the cavity 280. Said differently, the heat spreader component 118 is sized and shaped to manage heat for the memory package 114 component, and therefore the cavity 280 and/or the heat spreader component 118 does not extend leftward in the figure, over the package substrate 104.

As shown in FIGS. 2A, 2B, and 2D, and also as mentioned above, embodiments may include an interposer component 126. The interposer component 126 may have a function that is limited to providing structural support for the module layer 116. The interposer 126 component may extend around a portion of the lateral periphery of the memory package 114 component (see, e.g., area 294, where a memory package 114 component may be placed during assembly). In other embodiments, the interposer component 126 may additionally have a function of providing routing therethrough (e.g., from the motherboard 102 to the module layer 116) for power management (controlling the delivery of power and/or providing power to components) with routing indicated by traces 292.

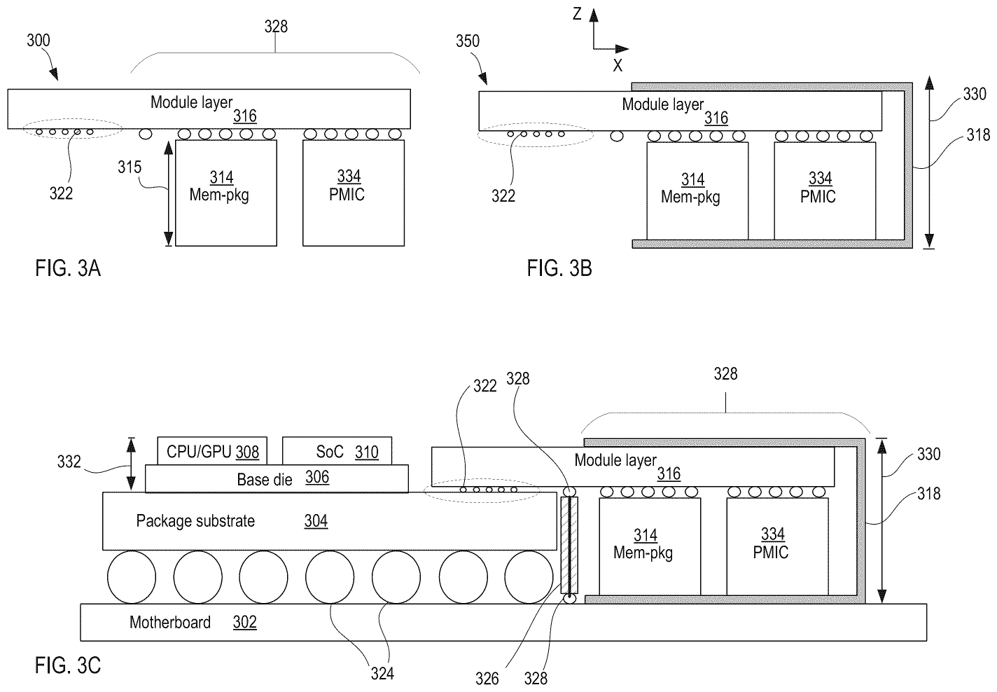

FIGS. 3A-3C illustrate additional embodiments, in which the low-profile memory apparatus 300 includes a memory package 314 component plus a power management integrated circuit (PMIC) 334. In these embodiments, the memory package 314 component is inverted/reversed and attached to a first arrangement of conductive contacts on the lower surface of the module layer 316, as described above, and, in addition, the PMIC 334 is also inverted/reversed and attached to the lower surface of the module layer 316, at a third arrangement of conductive contacts. The PMIC 334 is flipped upside-down, having its contacts on an upper surface and soldered 328 to the third arrangement of conductive contacts on the lower surface of the module layer 316, as shown in embodiment 300. The PMIC 334 and memory package 314 component share a substantially same height 315. As with other embodiments, the module layer 316 may have, external to the heat spreader component 318, a second arrangement of conductive contacts, and solder bumps 322 may or may not be present in embodiment 300 and embodiment 350.

Embodiment 350 illustrates a low-profile memory apparatus that includes a means for spreading heat, such as a heat spreader component 318. The heat spreader component 318 has a cavity, as before, but here the cavity has the dimensions that enable it to partially enclose the combination of the memory package 314 component and the PMIC 334, plus the portion of the module layer that has both the first arrangement and third arrangement (328) of conductive contacts. Said differently, the memory package 314 component, PMIC 334, and portion of the module layer 316 that includes the first arrangement and third arrangement 328 are located in the cavity. In various embodiments, the arrangements described are analogous to pinouts. As described above, “partially enclosing” means two substantially planar plates (e.g., a top plate and a bottom plate), attached on one side to a wall having a “z-height” 330. The z-height 330 of the low-profile memory apparatus represents a combined height of the heat spreader component 118, the memory package 114, the PMIC 334, the module layer 116, and associated means for attachment, such as solder bumps 328.

FIG. 3C illustrates the low-profile memory apparatus of embodiment 300 and embodiment 350 assembled with a processor package, on a motherboard 302, in accordance with various embodiments disclosed herein. As used herein, the processor package is as defined above, comprising a CPU or GPU die 308 (alternately referred to as a GT die) and a system on chip (SoC) 310. In various embodiments, the CPU 308 die and SoC 310 die may operate at conventionally high speeds, wherein “high speed” means greater than 6 GHz. The CPU 308 die and SoC 310 die may be operably connected to a base die 306 that serves as an interposer that connects the CPU 308 and the SoC 310. As may be appreciated, this arrangement of die is just one example embodiment, in other multi-die assemblies, there may be a different arrangement of die that serve various other functions.

While the drawings are not necessarily to scale, it is intentional that the height 315 of the memory package 314 and/or the PMIC 334 is larger than a combined height 332 of the base die 306 plus the CPU 308, and/or the height 315 is larger than a combined height 332 of the base die 306 plus the SoC 310.

As with the previous embodiments, note that the top plate and bottom plate are substantially the same size. Note also that the module layer 316 extends out from the cavity of the heat spreader component 318, such that an area that includes solder bumps 122 is not inside the heat spreader component 318. Said differently, the heat spreader component 318 is sized and shaped to manage heat for the memory package 314 component plus PMIC 334, and therefore the heat spreader component 118 does not extend leftward in the figure, over the package substrate 304.

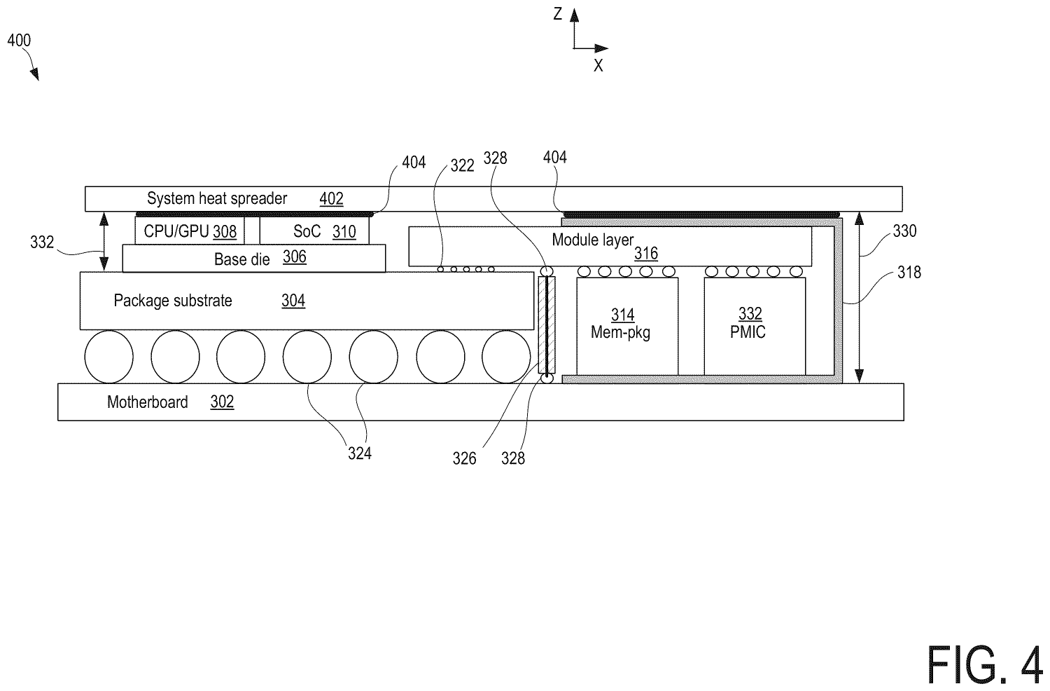

FIG. 4 is a front view of an example package assembly, multi-die assembly 400, that implements the low-profile memory apparatus of FIG. 3A and/or FIG. 3B. The multi-die assembly 400 further includes a processor package, as described hereinabove. In further embodiments, the multi-die assembly 400 may include additional IC die and may comprise a motherboard 302.

As shown in FIG. 4, in various embodiments, a means for thermal management, or system thermal solution 402 may be implemented over the processor package and low-profile memory apparatus. The means for thermal management or system thermal solution 402 may include a system head spreader component, a vapor chamber, a heat pipe, a heat sink, or a liquid-cooled cold plate attached to the multi-die assembly 400, located above/on the upper surfaces of the processor package and low-profile memory apparatus, as illustrated in the figures. As part of a system thermal solution, a thermal conduction layer interface material (TIM) 404 may be located over the upper surfaces of the die in the processor package and under the system thermal solution 402. The TIM 204 can be any suitable material, such as a silver particle-filled thermal compound, thermal grease, phase change materials, indium foils, or graphite sheets. Thermal management solutions can also include an integrated heat spreader. In other embodiments, the die in the multi-die assembly 400 can be overmolded with an encapsulant. The encapsulant can comprise a molding compound, dielectric materials, metal, ceramic, plastic, or a combination thereof.

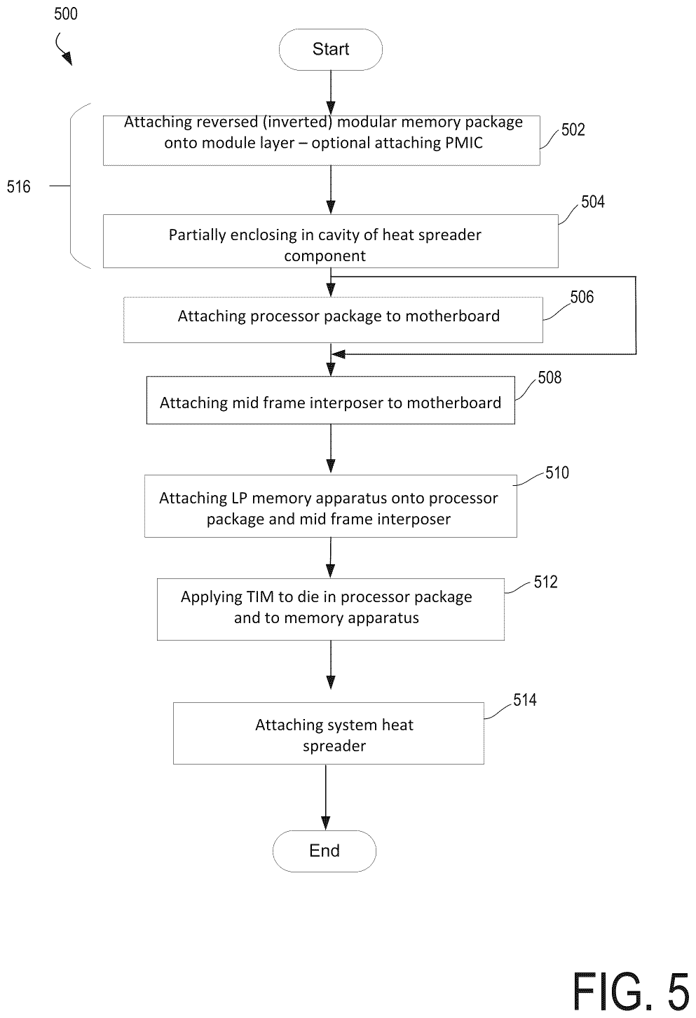

FIG. 5 provides an exemplary process flow 500 for creating embodiments described herein. At 502, the reversed or inverted modular memory package (114, 314) is attached to the module layer 116. Optionally, at 502, a PMIC 334 may also be inverted and attached to the module layer (116, 316). At 504, the embodiment from 502 is partially enclosed by a heat spreader component 118, e.g., located in a cavity of a heat spreader component 118 as described and illustrated herein, thereby creating a (low-profile) memory apparatus (for example, embodiment 150). Operations 502 and 504 are collectively referred to as memory apparatus assembly at 516.

At 506, processor package assembly is performed, and a processor package may be attached to a motherboard 102. Operation 506 may be referred to as processor package assembly, and may be performed separately from memory apparatus assembly 516, and embodiments of the process 500 flow may exclude 506, as indicated by the arrow.

At 508, preparation to attach a memory apparatus to a processor package may include attaching a mid-frame interposer or interposer component 126 to the motherboard 102.

At 510, the memory apparatus created at 516 is attached to a processor package, as described hereinabove. The memory apparatus may be attached to the package substrate 104 of the processor package, via the second arrangement of solder bumps 122. At 512, TIM may be applied to an upper surface of die in the processor package and to an upper surface of the memory apparatus. At 514, a system thermal solution (202, 402) is attached to the embodiment created at 512.

As mentioned, in some embodiments, after the operations at 504 are completed, the process moves to 508, when an interposer or support structure is desired, or to 510, attaching the memory package to the package substrate of an assembled processor package, and then moves to 512 and 514 to apply a system thermal solution (202, 402). After 514, the process 500 may end or repeat.

Thus, the low-profile memory apparatus compatible with system thermal solutions and method for making have been described. To summarize, unique features of the low-profile memory apparatus include (1) an inverted or reversed memory package component attached on a separate module substrate layer (i.e., different than the package substrate), (2) a substantially c-shaped heat spreader component partially enclosing the memory package component and substrate layer, and (3) a portion of the module layer being configured for providing electrical connection to the package substrate. When this low-profile memory apparatus is attached to a processor package on a motherboard, the final assembled z-height is smaller than other available solutions. Provided embodiments allow for interchangeability of memory package 114 components (e.g., various suppliers) and power management (PMIC) components. A “mid-frame” interposer may be used for structural support and to deliver power, improving performance. Routing paths to and from the memory package 114 components can be local and short. Printed circuit board (PCB, or package substrate 104, 304) area savings can be realized by moving memory bandwidth routing to a motherboard (102, 302).

The following description and associated figures provide more detail for components referenced hereinabove.

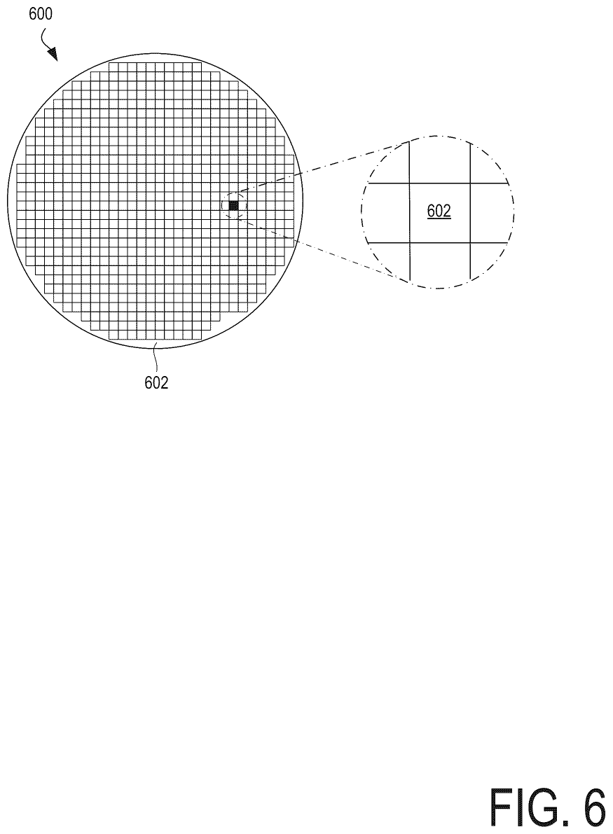

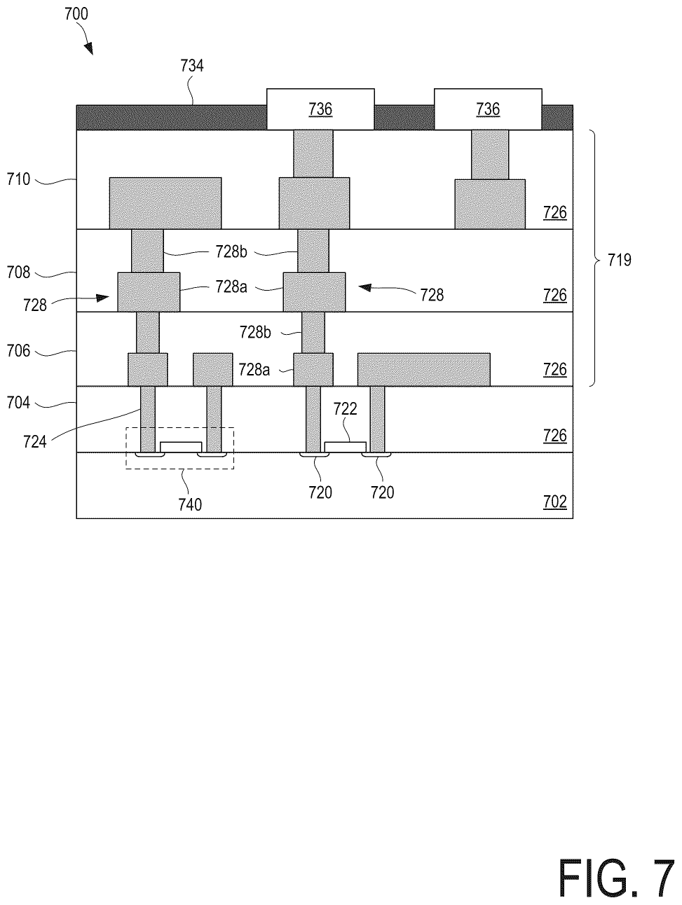

FIG. 6 is a top view of a wafer 600 and dies 602 that may be included in any of the embodiments disclosed herein. The wafer 600 may be composed of semiconductor material and may include one or more dies 602 formed on a surface of the wafer 600. After the fabrication of the integrated circuit components on the wafer 600 is complete, the wafer 600 may undergo a singulation process in which the dies 602 are separated from one another to provide discrete “chips” or destined for a packaged integrated circuit component. The individual dies 602, comprising an integrated circuit component, may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array. In some embodiments, a die 602 may be attached to a wafer 600 that includes other die, and the wafer 600 is subsequently singulated, this manufacturing procedure is referred to as a die-to-wafer assembly technique.

FIG. 7 is a cross-sectional side view of an integrated circuit 700 that may be included in any of the embodiments disclosed herein. One or more of the integrated circuits 700 may be included in one or more dies 602 (FIG. 6). The integrated circuit 700 may be formed on a die substrate 702 (e.g., the wafer 600 of FIG. 6) and may be included in a die (e.g., the die 602 of FIG. 6).

The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit 700 may be used. The die substrate 702 may be part of a singulated die (e.g., the dies 602 of FIG. 6) or a wafer (e.g., the wafer 600 of FIG. 6).

The integrated circuit 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720.

The gate 722 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may comprise a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be conducted to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuits having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit 700 with another component (e.g., a printed circuit board). The integrated circuit 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit 700 is a double-sided die, the integrated circuit 700 may include another metallization stack (not shown) on the opposite side of the device layer(s) 704. This metallization stack may include multiple interconnect layers as discussed above with reference to the interconnect layers 706-710, to provide electrically conductive paths (e.g., including conductive lines and vias) between the device layer(s) 704 and additional conductive contacts (not shown) on the opposite side of the integrated circuit 700 from the conductive contacts 736.

In other embodiments in which the integrated circuit 700 is a double-sided die, the integrated circuit 700 may include one or more through-silicon vias (TSVs) through the die substrate 702; these TSVs may make contact with the device layer(s) 704, and may provide electrically conductive paths between the device layer(s) 704 and additional conductive contacts (not shown) on the opposite side of the integrated circuit 700 from the conductive contacts 736. In some embodiments, TSVs extending through the substrate can be used for routing power and ground signals from conductive contacts on the opposite side of the integrated circuit 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuits 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

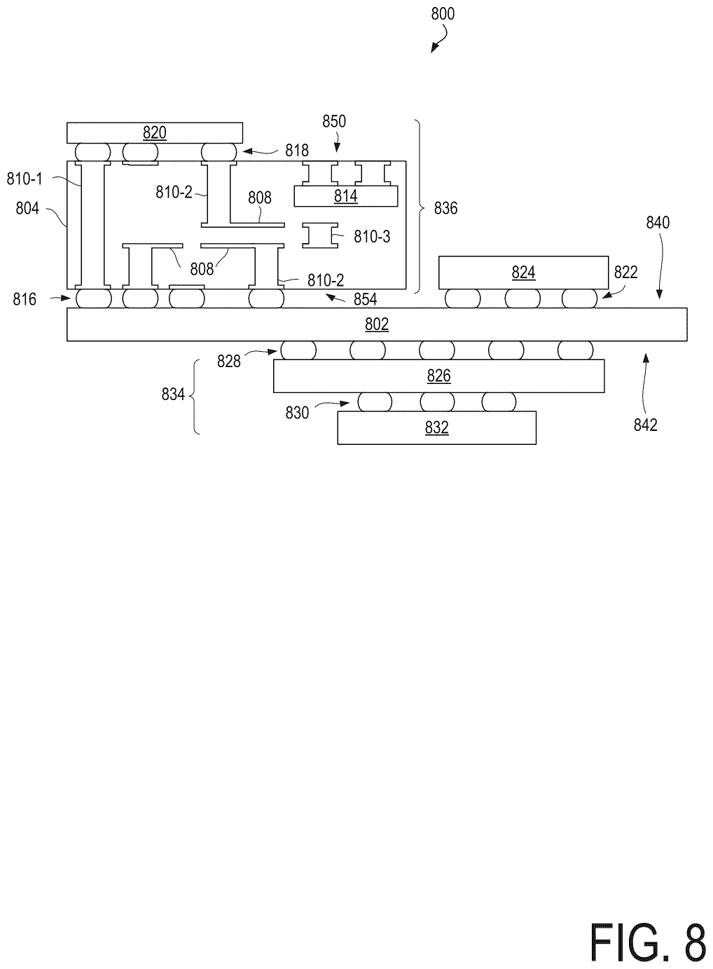

FIG. 8 is a cross-sectional side view of a microelectronic assembly 800 that may include any of the embodiments disclosed herein. The microelectronic assembly 800 includes multiple integrated circuit components disposed on a circuit board 802 (which may be a motherboard, system board, mainboard, etc.). The microelectronic assembly 800 may include components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The microelectronic assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit component that includes one or more integrated circuit dies (e.g., the die 602 of FIG. 6, the integrated circuit 700 of FIG. 7) and/or one or more other suitable components.

The unpackaged integrated circuit component 820 comprises solder bumps attached to contacts on the die. The solder bumps allow the die to be directly attached to the interposer 804. In embodiments where the integrated circuit component 820 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through-silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The integrated circuit assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, any suitable ones of the components of the electrical device 900 may include one or more of the PICs in embodiment 300, PICs in embodiment 430, package assemblies, microelectronic assemblies 800, integrated circuit components 820, integrated circuits 700, integrated circuit dies 602, or structures disclosed herein. A number of components are illustrated in FIG. 9 as included in the electrical device 900, but any one or more of these components may be omitted or duplicated, as suitable for the application. In some embodiments, some or all the components included in the electrical device 900 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 900 can comprise one or more processor units 902 that are heterogeneous or asymmetric to another processor unit 902 in the electrical device 900. There can be a variety of differences between the processor units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include power supply such as a battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Thus, embodiments of an improved via structure for use with the embedded component have been provided. The provided embodiments advantageously enable the use of finer pitch architectures and high-density input/output (I/O) designs in multi-chip packaging.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### Examples

Example 1 is an apparatus, comprising: a substrate layer with an upper surface and a lower surface, a portion of the substrate layer having a first arrangement of conductive contacts located on the lower surface; a memory package attached to the first arrangement of conductive contacts; a heat spreader component comprising a cavity; the memory package and the portion of the substrate layer having the first arrangement of conductive contacts located in the cavity; and a second arrangement of conductive contacts located on the lower surface of the substrate layer, the second arrangement of conductive contacts located external to the heat spreader component.

Example 2 includes the subject matter of Example 1, wherein the memory package is attached to the substrate layer with solder bumps.

Example 3 includes the subject matter of any one of Examples 1-2, wherein the heat spreader component comprises a metal.

Example 4 includes the subject matter of any one of Examples 1-2, wherein the heat spreader component comprises aluminum or copper.

Example 5 includes the subject matter of any one of Examples 1-4, further comprising: a package substrate with a first surface and a second surface; a processor package attached to the first surface of the package substrate; and the substrate layer attached, via the second arrangement of conductive contacts, to the first surface of the package substrate.

Example 6 includes the subject matter of any one of Examples 1-5, wherein the package substrate is a printed circuit board.

Example 7 is a package assembly including the subject matter of any one of Examples 1-5, and further comprising a printed circuit board attached to the second surface of the package substrate.

Example 8 includes the subject matter of any one of Examples 1-7, further comprising a system heat spreader attached above the processor package and above the substrate layer.

Example 9 includes the subject matter of any one of Examples 1-5 or Example 7, further comprising an integrated circuit component attached to the printed circuit board.

Example 10 includes the subject matter of Example 8, further comprising a thermal interface material (TIM), located between the system heat spreader and the heat spreader component.

Example 11 is a device comprising the subject matter of Example 9 or Example 10, and further comprising one or more of a power supply and a communication system.

Example 12 includes the subject matter of any one of Examples 1-5 or Examples 7-11, further comprising: a third arrangement of conductive contacts located on the lower surface of the substrate layer; a power management integrated circuit (PMIC) attached to the third arrangement of conductive contacts; and the PMIC located in the cavity.

Example 13 is a system comprising: a substrate layer with an upper surface and a lower surface, a portion of the substrate layer having a first arrangement of conductive contacts located on the lower surface; a memory package attached to the first arrangement of conductive contacts; a means for thermal management comprising a cavity; the memory package and the portion of the substrate layer having the first arrangement of conductive contacts located in the cavity; and a second arrangement of conductive contacts located on the lower surface of the substrate layer, the second arrangement of conductive contacts located external to the means for thermal management.

Example 14 includes the subject matter of Example 13, further comprising: a package substrate with a first surface and a second surface; a processor package attached to the first surface of the package substrate; and the substrate layer attached, via the second arrangement of conductive contacts, to the first surface of the package substrate.

Example 15 is a package assembly including the subject matter of Example 14, and further including a printed circuit board attached to the second surface of the package substrate.

Example 16 includes the subject matter of Example 15, further comprising a system heat spreader attached above the processor package and above the substrate layer.

Example 17 is a method, comprising: attaching an inverted modular memory component onto a lower surface of a substrate layer; partially enclosing substrate layer and modular memory component within a cavity of a heat spreader component, to thereby create a memory apparatus; attaching the memory apparatus onto a processor package; applying a thermal insulating material over the processor package and memory apparatus; and attaching a system heat spreader over the thermal insulating material.

Example 18 includes the subject matter of Example 17, further comprising attaching the processor package to a motherboard.

Example 19 includes the subject matter of Example 18, further comprising attaching a support structure between the motherboard and the lower surface of the substrate layer.

Example 20 includes the subject matter of Example 17, further comprising attaching a power management integrated circuit (PMIC) to the lower surface of the substrate layer; and locating the PMIC within the cavity of the heat spreader component.

What is claimed is:

1. An apparatus, comprising:
a substrate layer with an upper surface and a lower surface, a portion of the substrate layer having a first arrangement of conductive contacts located on the lower surface;
a memory package attached to the first arrangement of conductive contacts;
a heat spreader component comprising a cavity;
the memory package and the portion of the substrate layer having the first arrangement of conductive contacts located in the cavity; and
a second arrangement of conductive contacts located on the lower surface of the substrate layer, the second arrangement of conductive contacts located external to the heat spreader component.

2. The apparatus of claim 1, wherein the memory package is attached to the substrate layer with solder bumps.

3. The apparatus of claim 1, wherein the heat spreader component comprises a metal.

4. The apparatus of claim 1, wherein the heat spreader component comprises aluminum.

5. The apparatus of claim 1, further comprising:
a package substrate with a first surface and a second surface;
a processor package attached to the first surface of the package substrate; and
the substrate layer attached, via the second arrangement of conductive contacts, to the first surface of the package substrate.

6. The apparatus of claim 5, wherein the package substrate is a printed circuit board.

7. A package assembly comprising the apparatus of claim 5, and further comprising a printed circuit board attached to the second surface of the package substrate.

8. The package assembly of claim 7, further comprising a system heat spreader attached above the processor package and above the substrate layer.

9. The package assembly of claim 7, further comprising an integrated circuit component attached to the printed circuit board.

10. The package assembly of claim 8, further comprising a thermal interface material (TIM), located between the system heat spreader and the heat spreader component.

11. A device comprising the apparatus of claim 9, and further comprising one or more of a power supply and a communication system.

12. The apparatus of claim 1, further comprising:
a third arrangement of conductive contacts located on the lower surface of the substrate layer;
a power management integrated circuit (PMIC) attached to the third arrangement of conductive contacts; and
the PMIC located in the cavity.

13. A system comprising:
a substrate layer with an upper surface and a lower surface, a portion of the substrate layer having a first arrangement of conductive contacts located on the lower surface;
a memory package attached to the first arrangement of conductive contacts;
a means for thermal management comprising a cavity;
the memory package and the portion of the substrate layer having the first arrangement of conductive contacts located in the cavity; and
a second arrangement of conductive contacts located on the lower surface of the substrate layer;
the second arrangement of conductive contacts located external to the means for thermal management.

14. The system of claim 13, further comprising:
a package substrate with a first surface and a second surface;
a processor package attached to the first surface of the package substrate; and
the substrate layer attached, via the second arrangement of conductive contacts, to the first surface of the package substrate.

15. A package assembly comprising the system of claim 14, and further comprising a printed circuit board attached to the second surface of the package substrate.

16. The package assembly of claim 15, further comprising a system heat spreader attached above the processor package and above the substrate layer.

17. A method, comprising:
attaching an inverted modular memory component onto a lower surface of a substrate layer;
partially enclosing substrate layer and modular memory component within a cavity of a heat spreader component, to thereby create a memory apparatus;
attaching the memory apparatus onto a processor package;
applying a thermal insulating material over the processor package and memory apparatus; and
attaching a system heat spreader over the thermal insulating material.

18. The method of claim 17, further comprising attaching the processor package to a motherboard.

19. The method of claim 18, further comprising attaching a support structure between the motherboard and the lower surface of the substrate layer.

20. The method of claim 17, further comprising attaching a power management integrated circuit (PMIC) to the lower surface of the substrate layer; and
locating the PMIC within the cavity of the heat spreader component.
